(19) United States
(12) Patent Application Publication
(10) Pub. No.: US 2024/0291130 A1
(43) Pub. Date: Aug. 29, 2024

(54) Directional Coupler and Associated Ground Structure

(71) Applicant: Qualcomm Incorporated, San Diego, CA (US)

(72) Inventor: Boddepalli Venkata Raj Gopalarao, Chennai (IN)

(21) Appl. No.: 18/174,918

(22) Filed: Feb. 27, 2023

(51) Int. Cl. H01P 3/08; H01P 5/18; H05K 1/02

(52) U.S. Cl. CPC H01P 3/08; H01P 5/18; H05K 1/0243

(57) ABSTRACT

An apparatus is disclosed with a directional coupler and associated ground structure. In example aspects, the apparatus includes a printed circuit board. The printed circuit board includes a first layer and a second layer. The first layer includes a first transmission line and a second transmission line. The second transmission line includes at least one bend and is configured to electromagnetically couple to the first transmission line. The second transmission line is spaced apart from the first transmission line to form a gap in the first layer between the first transmission line and the second transmission line. The second layer includes a metal structure configured to provide a ground for the first transmission line. The metal structure includes an aperture positioned to at least partially overlap the gap in the first layer.

### TECHNICAL FIELD

This disclosure relates generally to signal communication or signal processing using an electronic device and, more specifically, to a directional coupler and associated ground structure that may achieve a target coupling factor.

### BACKGROUND

Electronic devices include traditional computing devices such as desktop computers, notebook computers, smartphones, wearable devices like a smartwatch, internet servers, and so forth. Electronic devices also include other types of computing devices such as personal voice assistants (e.g., smart speakers), wireless access points or routers, thermostats and other automated controllers, robotics, automotive electronics, devices embedded in other machines like refrigerators and industrial tools, Internet of Things (IoT) devices, medical devices, and so forth. These various electronic devices provide services relating to productivity, communication, social interaction, security, health and safety, remote management, entertainment, transportation, and information dissemination. Thus, electronic devices play crucial roles in modern society.

Many of the services provided by electronic devices in today's interconnected world depend at least partly on electronic communications. Electronic communications can include, for example, those exchanged between two or more electronic devices using wireless or wired signals that are transmitted over one or more networks, such as the Internet, a Wi-Fi® network, or a cellular network. Electronic communications can therefore include wireless or wired transmissions and receptions. To transmit and receive communications, an electronic device can use a transceiver, such as a wireless transceiver that is designed for wireless communications.

Some electronic communications can thus be realized by propagating signals between two wireless transceivers at two different electronic devices. For example, using a wireless transmitter, a smartphone can transmit a wireless signal to a base station over the air as part of an uplink communication to support mobile services. Using a wireless receiver, the smartphone can receive a wireless signal that is transmitted from the base station via the air medium as part of a downlink communication to enable mobile services. With a smartphone, for instance, mobile services can include making voice and video calls, participating in social media interactions, sending messages, watching movies, sharing videos, performing searches, using map information or navigational instructions, finding friends, engaging in location-based services generally, transferring money, obtaining another service like a car ride, and so forth. A smartphone or other electronic device can also communicate with a network via an access point (AP), such as a Wi-Fi® access point or router, to participate in mobile services or engage in other communications.

Accordingly, many mobile and other communication-based services depend at least partly on the transmission or reception of wireless signals between two or more electronic devices. Consequently, researchers, electrical engineers, and other designers of electronic devices strive to develop wireless transceivers and associated hardware that can use wireless signals effectively to provide mobile services, various features that are convenient for users, and even functions that are critical for modern society.

### SUMMARY

A directional coupler is a passive component that is capable of sampling a signal, including a signal that is propagating at a radio frequency (RF). The sampled signal can be used for signal processing to improve wireless communications, such as by increasing efficiency or facilitating the sharing of the electromagnetic (EM) spectrum. In some implementations, a directional coupler includes two transmission lines: a main transmission line that propagates a signal and a coupled transmission line that electromagnetically samples the signal propagating along the main transmission line. In example implementations, to reduce a size of the directional coupler, the coupled transmission line is meandered using multiple bends. The bends enable a transmission line of a given length to occupy a smaller area. These bends, however, can degrade the coupling factor and isolation of the directional coupler. To counteract this effect, the transmission lines are spatially paired with an associated ground structure. For example, a metal structure can include an aperture that overlaps a gap present between the two transmission lines. The metal structure can form a ground plane in a layer that is different from another layer that contains the two transmission lines. In some cases, the aperture can be slot-shaped (or have a slot shape) to match at least a portion of a shape of the gap. The aperture in the metal structure can decrease the coupling factor and increase the isolation, which in turn can increase the directivity of the directional coupler. These and other implementations are described herein.

In an example aspect, an apparatus is disclosed. The apparatus includes a printed circuit board with a first layer and a second layer. The first layer includes a first transmission line and a second transmission line. The second transmission line is configured to electromagnetically couple to the first transmission line and includes at least one bend. The second transmission line is spaced apart from the first transmission line to form a gap in the first layer between the first transmission line and the second transmission line. The second layer includes a metal structure configured to provide a ground for the first transmission line. The metal structure includes an aperture positioned to at least partially overlap the gap in the first layer.

In an example aspect, an apparatus for electromagnetic coupling is disclosed. The apparatus includes a directional coupler and a metal structure. The directional coupler includes a main transmission line disposed in a first layer of a printed circuit board. The directional coupler also includes a meandered transmission line disposed in the first layer of the printed circuit board. The meandered transmission line is configured to electromagnetically couple to the main transmission line. The meandered transmission line is spaced apart from the main transmission line to form a gap in the first layer between the main transmission line and the meandered transmission line. The metal structure is disposed in a second layer of the printed circuit board. The metal structure includes means for increasing a directivity of the directional coupler by reducing a coupling factor.

In an example aspect, a method for manufacturing a printed circuit board is disclosed. The method includes providing at least one substrate for the printed circuit board. The method also includes disposing on the at least one substrate a first layer including a first transmission line and a second transmission line, with the second transmission line configured to electromagnetically couple to the first transmission line. The second transmission line includes at least one bend, and the second transmission line is spaced apart from the first transmission line to form a gap in the first layer between the first transmission line and the second transmission line. The method further includes disposing on the at least one substrate a second layer including a metal structure configured to provide a ground for the first transmission line, with the metal structure including an aperture positioned to at least partially overlap the gap in the first layer.

### BRIEF DESCRIPTION OF DRAWINGS

FIG. 1 illustrates an environment with example electronic devices that have a wireless interface device, which includes an example radio-frequency front-end having a directional coupler.

FIG. 2 illustrates an example wireless interface device including a power amplifier, a directional coupler, and a feedback loop.

FIG. 3 illustrates an example directional coupler with two transmission lines and four ports.

FIG. 4-1 is an exploded diagram of an example printed circuit board (PCB) that includes multiple layers in which a directional coupler and associated ground structure can be implemented.

FIG. 4-2 is an exploded diagram of a PCB including a first layer with a directional coupler and a second layer with a metal structure having an aperture.

FIGS. 5-1, 5-2, and 5-3 are schematic diagrams of an example directional coupler with a first transmission line and a second transmission line that meanders in conjunction with three respective example implementations of an associated aperture.

FIG. 6-1 is a schematic diagram of an example directional coupler with a first transmission line and a second transmission line that meanders.

FIG. 6-2 is a schematic diagram of an example metal structure having an aperture that can be spatially mated to the directional coupler of FIG. 6-1.

FIG. 6-3 is a schematic diagram of the example aperture of FIG. 6-2 superimposed over the example directional coupler of FIG. 6-1 in an example relative spatial arrangement.

FIG. 6-4 is a schematic diagram of the example aperture of FIG. 6-2, in conjunction with the corresponding metal structure that forms the aperture, layered over the example directional coupler of FIG. 6-1.

FIG. 7 is a flow diagram illustrating an example process for manufacturing a directional coupler and associated ground structure.

### DETAILED DESCRIPTION

### Introduction and Overview

To provide mobile services and other wireless features and functions, electronic devices typically use a wireless interface device to communicate wireless signals in accordance with some wireless standard. Examples of relatively older wireless standards include a 4th Generation (4G) cellular standard and an IEEE 802.11b or 802.11g Wi-Fi® standard, both of which are used today with smartphones and other connected devices. These wireless standards enable a certain wireless communication speed and efficiency. To enable faster and more efficient wireless networks, efforts are underway to create newer wireless standards. Next-generation cellular networks and advanced Wi-Fi® networks, for example, are expected to offer significantly higher bandwidths, lower latencies, and access to additional portions of the electromagnetic (EM) spectrum. Taken together, this means that new wireless services can be provided to users, such as safer self-driving vehicles, augmented reality (AR) and other mixed reality (MR) imaging, on-the-go 4K video streaming, ubiquitous sensors to keep people safe and to use natural resources more efficiently, real-time language translations, and so forth.

To make these new, faster wireless technologies more widely available, many wireless devices besides smartphones and other traditional computing devices will be deployed, which is sometimes referred to as the “Internet of Things” (IoT). Compared to today's use of wireless devices, hundreds of billions of additional devices are expected to be connected to the internet with the arrival of the Internet of Things. These IoT devices may include, for instance, small, inexpensive, and low-powered devices, like sensors and tracking tags. To enable next-generation wireless technologies, some IoT devices and many electronic devices generally will operate in accordance with 5th Generation (5G) cellular standards and beyond as well as newer Wi-Fi® standards. Such devices will communicate with signals that use wider frequency ranges that are located at higher frequencies of the EM spectrum as compared to those devices that operate in accordance with older wireless standards. For example, many newer devices will be expected to operate at millimeter wave (mmWave) frequencies (e.g., frequencies between at least 24 and 300 Gigahertz (GHz)), as well as at frequencies in the single-digit GHz range, such as 4.5 to 7.5 GHZ.

To accommodate these commercial expectations and surmount the associated technical hurdles, the physical components that enable wireless communications under these constraints will be expected to operate efficiently at higher frequencies. One component that facilitates electronic communication is the wireless interface device. The wireless interface device can include a communication processor, a wireless transceiver, and a radio-frequency front-end (RFFE). Unfortunately, the wireless interface devices designed for electronic devices that operate in accordance with older Wi-Fi® and 4G wireless standards are not adequate for the newer Wi-Fi®; and 5G wireless standards, for these standards are expected to accommodate higher frequencies, involve more-stringent latency demands, and meet tighter fiscal constraints.

Consequently, to facilitate the adoption of newer and faster cellular and Wi-Fi® technologies, as well as the widespread deployment of electronic devices that can provide new capabilities and services, wireless interface devices will be deployed having designs that can communicate at GHz frequencies. These wireless interface devices will also be designed to share the available EM spectrum more efficiently. Electrical engineers and other designers of electronic devices are therefore striving to develop new wireless interface devices that will enable the promise of Sub-6 GHZ, 5G cellular, 5G and 6G bands for Wi-Fi®, and other higher-frequency technologies to become a reality.

A wireless interface device can include, for example, one or more switches, multiple filters, at least one amplifier, and processing circuitry. These components may be distributed across various portions of the wireless interface device, such as the communication processor, the wireless transceiver, or the RF front-end. For example, the communication processor may include control circuitry, such as a closed-loop controller. In some cases, the RF front-end includes a power amplifier that provides a signal to a filter of the RF front-end for transmission. The transceiver can include a feedback receiver that is coupled to the output of the power amplifier via a directional coupler. In operation, as part of a feedback loop, the feedback receiver provides an indication of the signal output by the power amplifier to the closed-loop controller. The closed-loop controller can adjust the signal processing based on the output of the power amplifier as provided by the directional coupler.

For example, the closed-loop controller can implement transmit power control (TPC), digital predistortion (DPD), error vector magnitude (EVM) correction, and so forth to facilitate the power amplifier or another component or aspect of a transmit chain attaining one or more target operational parameters. The closed-loop controller can improve operation of the power amplifier based on obtaining an accurate indication of the signal output by the power amplifier. In other words, the capability of the closed-loop controller may be impaired if the accuracy of the indication is reduced. Thus, the quality of the directional coupler can impact how well the feedback loop can improve performance of the wireless interface device. If the directional coupler fails to provide an accurate indication of the power output by the power amplifier, the feedback receiver is unable to provide an accurate indication of the output signal to the closed-loop controller. The closed-loop controller may therefore be unable to properly control the transmission of wireless signals to meet target operational parameters.

Accordingly, an accuracy of a sampled signal provided by a directional coupler is one factor determining the quality of the directional coupler. There are, however, other factors. For example, a degree to which the directional coupler affects the signal being sampled is a second factor. A third factor is cost, which may be impacted by a size of the directional coupler and/or whether the directional coupler is implemented as a separate, individual physical component or as part of some other component.

As described above, a directional coupler can be part of a transmit chain. The directional coupler can be coupled between, for example, a power amplifier and a filter, such as a bandpass filter. Although certain examples are described herein in the context of a transmit chain implementation, the principles are applicable to directional couplers that are deployed in a receive chain, in another portion of a wireless interface device, or in another part of an electronic device generally.

In some approaches, the directional coupler is further coupled between the power amplifier and a switch. The directional coupler can be integrated into a single chip with the power amplifier, the switch, and a low-noise amplifier as part of a front-end module. The front-end module can then provide an indication of the output signal of the power amplifier to another module, such as a baseband transceiver, for further processing and/or for forwarding to a communication processor. With this approach, however, the directional coupler injects additional insertion loss into the transmit path, which can increase power demands or jeopardize transmit signal strength. This approach also limits the performance of the power amplifier in the transmitter. The power-amplifier performance limitation leads to limiting certain overall transmitter parameters, such as spectral emission mask (SEM) and EVM characteristics. The power-amplifier performance limitation also leads to an increase in the overall transmitter power consumption, which reduces the efficiency. The efficiency reduction is further multiplied by a quantity of transmit chains that a wireless interface device uses, which can be two, four, eight, or more.

In some other approaches, a front-end module can integrate into a single chip a power amplifier, a switch, and a low-noise amplifier. A directional coupler is then implemented as an external chip that is coupled between the front-end module and a filter, such as a bandpass filter, along a transmit chain. This approach thus creates an extra bill-of-materials (BOM) cost to include the directional coupler.

In example implementations as described herein, a directional coupler is deployed using a printed circuit board (PCB). The directional coupler can be coupled between, for instance, a module including RF front-end components and an antenna module including one or more filters and an antenna or an interface therefor. The directional coupler includes a first transmission line and a second transmission line disposed in one layer of the PCB. To produce a directional coupler in a compact area, the second transmission line includes multiple bends to realize a meandered transmission line. A gap is present between the first and second transmission lines.

To improve the directivity of the directional coupler, the coupling factor of the directional coupler is lowered by employing a disturbed ground structure. In a different layer of the PCB, a metal structure includes an aperture. In some cases, the gap and the aperture are aligned such that the aperture at least partially overlaps the gap. For instance, an axis that is substantially perpendicular to the layers of the PCB can extend through the aperture and the gap. The aperture can be customized based on a shape of the gap that results from the meandering of the second transmission line. These and other implementations are described herein.

By using a metal layer of a PCB to create the directional coupler, the cost falls to between negligible and zero, as the two transmission lines can be etched on the PCB like one of many other circuit components. This cost is appreciably lower than that of a separate module or chip as described above with regard to the approaches that involve an extra BOM cost. Further, a metal trace (e.g., a metal strip or wire) is produced (e.g., etched) on the PCB to propagate the amplified signal from the power amplifier to an antenna interface. This metal trace can perform a “double duty” by also being used as the first transmission line of the directional coupler. Accordingly, implementing a directional coupler on a PCB also results in little to substantially zero additional insertion loss for the transmit chain. This is appreciably less insertion loss than the approaches described above in which a directional coupler is integrated into a module with RF front-end components.

### Description Examples

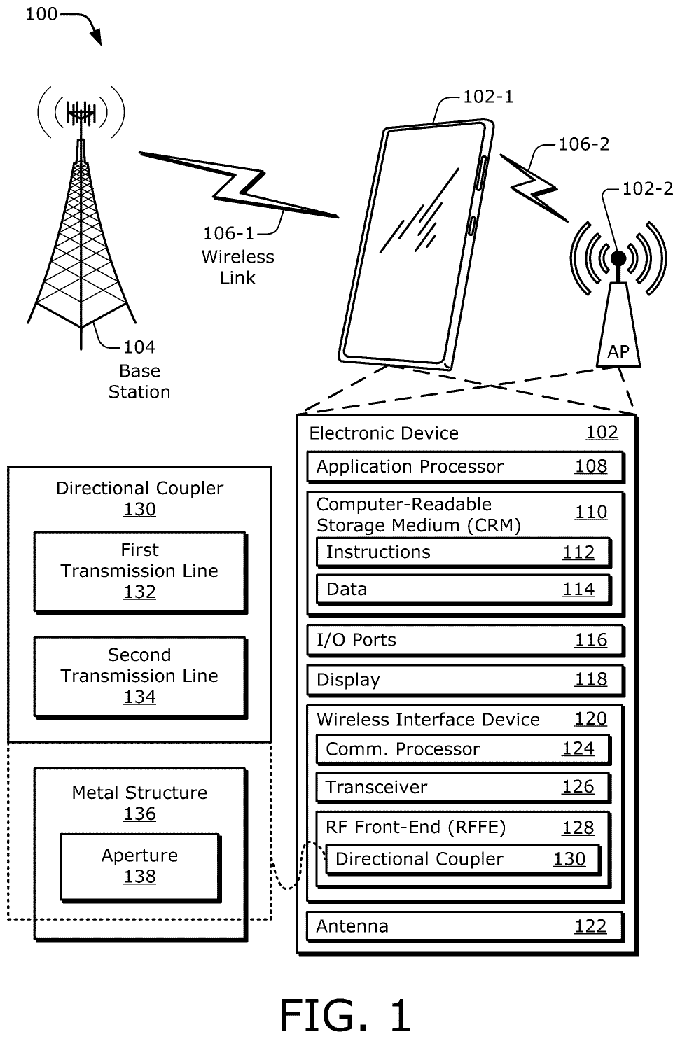

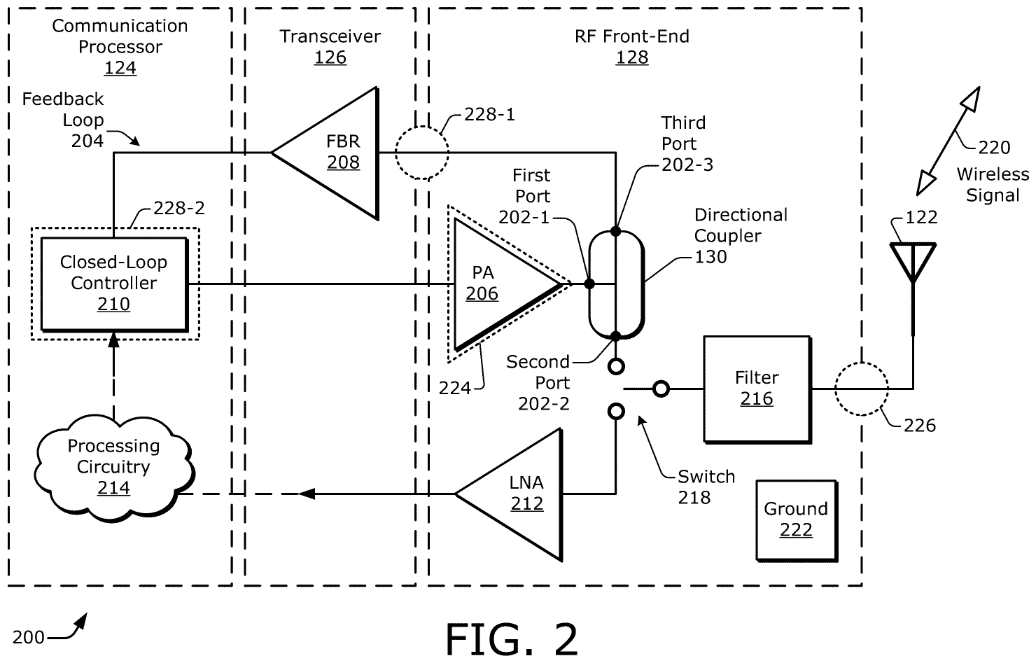

FIG. 1 illustrates an example environment 100 with at least one electronic device 102 that has a wireless interface device 120, which includes at least one directional coupler 130. This document describes example implementations of the directional coupler 130 and associated metal structure 136, which may be parts of a radio-frequency front-end (RF front-end) as shown. Additionally or alternatively, the directional coupler 130 and the associated metal structure 136 can be parts of a transceiver, a communication processor, or another portion of an apparatus, such as an electronic device 102. Two examples of an electronic device 102 are explicitly depicted: a mobile phone electronic device 102-1 and an access point electronic device 102-2. A directional coupler and associated ground structure can be implemented in these and other types of electronic devices.

In FIG. 1, the mobile phone electronic device 102-1 is depicted as a smartphone, and the access point electronic device 102-2 is depicted as a Wi-Fi® access point suitable for home or commercial use. An electronic device 102, however, may be implemented as any suitable computing or other electronic device. Examples of an apparatus that can be realized as an electronic device 102 include a cellular base station, broadband router, access point, cellular or mobile phone, gaming device, navigation device, media device, laptop computer, desktop computer, tablet computer, and server computer. Other examples of an apparatus that can be realized as an electronic device 102 include a network-attached storage (NAS) device, smart appliance, vehicle-based communication system, Internet of Things (IoT) device, sensor or security device, asset tracker, fitness management device, wearable device such as intelligent glasses or smartwatch, wireless power device (transmitter or receiver), medical device, and so forth. An electronic device 102 may be referred to with different terminology, such as a user equipment (UE) or a customer premises equipment (CPE).

In the environment 100, the access point electronic device 102-2 communicates with the mobile phone electronic device 102-1 with a wireless link 106-2. The mobile phone electronic device 102-1 communicates with a base station 104 through a wireless link 106-1. Generally, a base station 104 communicates with an electronic device 102 via a wireless link 106, which may be implemented as any suitable type of wireless link that carries a communication signal. Although depicted as a base station tower of a cellular radio network, the base station 104 may represent or be implemented as another device, such as a satellite, terrestrial broadcast tower, access point, peer-to-peer device, mesh network node, fiber optic line interface, another electronic device as described above generally, and so forth. Hence, the wireless link 106 can extend between the electronic device 102 and the base station 104 in any of various manners. Although certain example aspects are described below in terms of the base station 104 and/or the mobile phone electronic device 102-1, the components, communications, and principles are applicable to the access point electronic device 102-2. For example, the access point electronic device 102-2 can also communicate with the base state 104 via another wireless link (not explicitly shown).

The wireless link 106 can include a downlink of data or control information communicated from the base station 104 to the electronic device 102. The wireless link 106 can also include an uplink of other data or control information communicated from the electronic device 102 to the base station 104. The wireless link 106 may be implemented using any suitable wireless communication protocol or standard. Examples of such protocols and standards include a 3^{rd} Generation Partnership Project (3GPP) Long-Term Evolution (LTE) standard, such as a 4^{th} Generation (4G), a 5^{th} Generation (5G), or a 6^{th} Generation (6G) cellular standard; an IEEE 802.11 standard, such as 802.11g, ac, ax, ad, aj, or ay standard (e.g., Wi-Fi® 6 or WiGig®); an IEEE 802.16 standard (e.g., WiMAX®); a Bluetooth® standard; an ultra-wideband (UWB) standard (e.g., IEEE 802.15.4); and so forth. In some implementations, the wireless link 106 may provide power wirelessly, and the electronic device 102 or the base station 104 may comprise a power source or a power sink.

As shown for some implementations, the electronic device 102 can include at least one application processor 108 and at least one computer-readable storage medium 110 (CRM 110). The application processor 108 may include any type of processor, such as a central processing unit (CPU) or a multi-core processor, that is configured to execute processor-executable instructions (e.g., code) stored by the CRM 110. The CRM 110 may include any suitable type of data storage media, such as volatile memory (e.g., random-access memory (RAM)), non-volatile memory (e.g., Flash memory), optical media (e.g., a disc), magnetic media (e.g., a disk or tape), and so forth. In the context of this disclosure, the CRM 110 is implemented to store instructions 112, data 114, and other information of the electronic device 102, and thus the CRM 110 does not include transitory propagating signals or carrier waves.

The electronic device 102 may also include one or more input/output ports 116 (I/O ports 116) and at least one display 118. The I/O ports 116 enable data exchanges or interaction with other devices, networks, or users. The I/O ports 116 may include serial ports (e.g., universal serial bus (USB®) ports), parallel ports, network ports (e.g., Ethernet ports), audio ports, infrared (IR) ports, camera or other sensor ports, and so forth. The display 118 can be realized as a display screen or a projection that presents graphical images provided by other components of the electronic device 102, such as a user interface (UI) associated with an operating system, program, or application. Alternatively or additionally, the display 118 may be implemented as a display port or virtual interface through which graphical content of the electronic device 102 is communicated or presented. In some cases, such as with an example access point electronic device 102-2, the display 118 may include one or more light-emitting diodes or the like.

The electronic device 102 further includes at least one wireless interface device 120 and at least one antenna 122. The example wireless interface device 120 provides connectivity to respective networks and peer devices via a wireless link, which may be configured similarly to or differently from the wireless link 106. The wireless interface device 120 may facilitate communication over any suitable type of wireless network, such as a wireless local area network (LAN) (WLAN), wireless personal-area-network (PAN) (WPAN), peer-to-peer (P2P) network, mesh network, cellular network, wireless wide-area-network (WAN) (WWAN), and/or navigational network (e.g., the Global Positioning System (GPS) of North America or another Satellite Positioning System (SPS) or Global Navigation Satellite System (GNSS)). In the context of the example environment 100, the electronic device 102 can communicate various data and control information bidirectionally with the base station 104 via the wireless interface device 120. The electronic device 102 may, however, communicate directly with other peer devices, an alternative wireless network, an access point, and the like. Also, as described above, an electronic device 102 may alternatively be implemented as a base station 104, an access point electronic device 102-2, or another apparatus as set forth herein.

As shown in FIG. 1, the wireless interface device 120 can include at least one communication processor 124, at least one transceiver 126, and at least one radio-frequency front-end 128 (RFFE 128). These components process data information, control information, and signals associated with communicating information for the electronic device 102 via the antenna 122. The communication processor 124 may be implemented as at least part of a system-on-chip (SoC), as a modem processor, or as a baseband radio processor (BBP) that enables a digital communication interface for data, voice, messaging, or other applications of the electronic device 102. The communication processor 124 can include a digital signal processor (DSP), at least one controller, or one or more signal-processing blocks (not shown) for encoding and modulating data for transmission and for demodulating and decoding received data. Additionally, the communication processor 124 may also manage (e.g., control or configure) aspects or operation of the transceiver 126, the RF front-end 128, and other components of the wireless interface device 120 to implement various communication protocols or communication techniques.

In some cases, the application processor 108 and the communication processor 124 can be combined into one module or integrated circuit (IC), such as an SoC. Regardless, the application processor 108, the communication processor 124, or a processor generally can be operatively coupled to one or more other components, such as the CRM 110 or the display 118, to enable control of, or other interaction with, the various components of the electronic device 102. For example, at least one processor 108 or 124 can present one or more graphical images on a display screen implementation of the display 118 based on one or more wireless signals communicated (e.g., transmitted or received) via the at least one antenna 122 using components of the wireless interface device 120. Also, at least one processor 108 or 124 can coordinate transmission of one or more wireless signals using a component of the wireless interface device 120, such as the directional coupler 130. Further, the application processor 108 or the communication processor 124, including a combination thereof, can be realized using digital circuitry that implements logic or functionality that is described herein. Additionally, the communication processor 124 may also include or be associated with a memory (not separately depicted) to store data and processor-executable instructions (e.g., code), such as the same CRM 110 or another CRM.

Although not shown, the wireless interface device 120 can include at least one mixer circuit for frequency translation. For example, the transceiver 126 can include at least one mixer circuit, or the RF front-end 128 can include at least one mixer circuit (including both components can have at least one mixer circuit in accordance with an optional, but permitted herein, “inclusive-or” interpretation of the word “or”). The transceiver 126 can also include circuitry and logic for filtering, switching, amplification, channelization, frequency translation, and so forth.

Frequency translation functionality may include an up-conversion or a down-conversion of frequency that is performed through a single conversion operation (e.g., with a direct-conversion architecture) or through multiple conversion operations (e.g., with a superheterodyne architecture). The transceiver 126 can perform such frequency conversion (e.g., frequency translation) by using a mixer circuit and an associated local oscillator (not shown). Generally, the transceiver 126 can include filters, switches, amplifiers, mixers, and so forth for routing and conditioning signals that are transmitted or received via the antenna 122.

In addition to a mixer circuit and/or local oscillator, the transceiver 126 can include an analog-to-digital converter (ADC) or a digital-to-analog converter (DAC) (not shown). In operation, an ADC can convert analog signals to digital signals, and a DAC can convert digital signals to analog signals. Generally, an ADC or a DAC can be implemented as part of the communication processor 124, as part of the transceiver 126, or separately from both (e.g., as another part of an SoC or as part of the application processor 108).

The components or circuitry of the transceiver 126, as well as that of the RF front-end 128, can be implemented in any suitable fashion, such as with combined transceiver logic or separately as respective transmitter and receiver entities. In some cases, the transceiver 126, for instance, is implemented with multiple or different sections to implement respective transmitting and receiving operations (e.g., with separate transmit and receive chains). Although not shown in FIG. 1, the transceiver 126 may include logic to perform in-phase/quadrature (I/Q) operations, such as synthesis, phase correction, modulation, demodulation, and the like.

The RF front-end 128 can also include one or more mixers, one or more filters, one or more switches, or one or more amplifiers for conditioning signals received via the antenna 122 or for conditioning signals to be transmitted via the antenna 122. The RF front-end 128 may also include a local oscillator, phase shifter (PS), peak detector, power meter, gain control block, antenna tuning circuit, N-plexer, balun, and the like. Configurable components of the RF front-end 128, such as some phase shifters, an automatic gain controller (AGC), or a power amplifier with an adjustable amplification, may be controlled by the communication processor 124 to implement communications in various modes, with different frequency bands, or using beamforming. In some implementations, the antenna 122 is implemented as at least one antenna array that includes multiple antenna elements. Thus, as used herein, an “antenna” can refer to at least one discrete or independent antenna, to at least one antenna array that includes multiple antenna elements, or to a portion of an antenna array (e.g., an antenna element), depending on context or implementation.

In example implementations, the wireless interface device 120 includes at least one directional coupler 130 and at least one associated metal structure 136. In some implementations, the directional coupler 130 may be separate from the associated metal structure 136. In other implementations, the directional coupler 130 may include at least a portion of the associated metal structure 136, depending on context. These components may be positioned at the communication processor 124, the transceiver 126, the RF front-end 128, and so forth, including by being present at two or more sections or parts of the wireless interface device 120. In FIG. 1, an example directional coupler 130 is depicted as being part of the RF front-end 128. Described implementations of a directional coupler 130 can, however, additionally or alternatively be employed in other portions of the wireless interface device 120 or in other portions of the electronic device 102 generally.

As set forth above, a directional coupler 130 and associated metal structure 136 can be included in an electronic device besides a cell phone, such as a base station 104 or wireless access point electronic device 102-2. Other electronic device apparatuses that can employ a directional coupler 130 and associated metal structure 136 include a laptop, communication hardware of a vehicle, an IOT device, a wearable device, and so forth as described herein.

In example implementations, a directional coupler 130 can include a first transmission line 132 and a second transmission line 134. As part of or at least in association with the directional coupler 130, the RF front-end 128 (or other section of the wireless interface device 120) includes a metal structure 136. The metal structure 136 includes or defines an aperture 138. The aperture 138 can be realized as a hole, an opening, a slot, a missing portion or absence of metal, and so forth with respect to the metal structure 136. As indicated by short dashed lines, the metal structure 136 may be separate from the directional coupler 130, or at least a portion of the metal structure 136 may be part of the directional coupler 130. For example, the aperture 138 and/or a part of the metal structure 136 that defines the aperture 138 may be part of the directional coupler 130.

Examples of directional couplers are described below with reference to FIGS. 3, 4-1, 4-2, 5-1 to 5-3, and 6-1 to 6-4. Next, however, this document describes example implementations of a wireless interface device 120 that employs a directional coupler 130 for feedback-based control operations, such as TPC and DPD.

FIG. 2 illustrates, at 200 generally, an example wireless interface device 120 (e.g., of FIG. 1) that includes multiple components in an example environment in which a directional coupler 130 and associated metal structure 136 can be employed. Example components may include at least one closed-loop controller 210, at least one power amplifier 206 (PA 206), at least one directional coupler 130, at least one feedback receiver 208 (FBR 208), and processing circuitry 214. As shown, the directional coupler 130 includes at least a first port 202-1, a second port 202-2, and a third port 202-3. FIG. 2 also depicts a low-noise amplifier 212 (LNA 212), at least one switch 218, at least one filter 216, and at least one antenna 122. Other wireless interface device implementations, however, may include more, fewer, or different components. For example, the at least one feedback receiver 208 can be omitted.

In example implementations, these components can be disposed at, or can be part of, one or more portions of the wireless interface device 120 (e.g., of FIG. 1). These portions include the communication processor 124, the transceiver 126, and the RF front-end 128. As shown in FIG. 2, the communication processor 124 includes the closed-loop controller 210 and the processing circuitry 214, and the transceiver 126 includes the feedback receiver 208. The RF front-end 128 includes the power amplifier 206, the directional coupler 130, the low-noise amplifier 212, the switch 218, and the filter 216. A ground 222 (e.g., an electrical ground) is also depicted as being part of at least the RF front-end.

These components can, however, be part of different portions of the wireless interface device 120. Further, these portions of the wireless interface device 120, as well as the illustrated components thereof, may be manufactured to be separate from each other or integrated with one or more other parts or components. For example, the communication processor 124 and at least part of the transceiver 126 may be integrated into one integrated circuit (IC) or one printed circuit board (PCB). Further, one or more of the illustrated components of the RF front-end 128 can be integrated together and/or with at least some of the components of the transceiver 126 into another IC or PCB. These various parts may also be combined into one or more packages and/or mounted on at least one printed circuit board (PCB), such as a flexible or a rigid PCB.

As illustrated by way of example, the switch 218 is coupled between the power amplifier 206 (via the directional coupler 130), the low-noise amplifier 212, and the filter 216. The filter 216 is coupled between the switch 218 and an interface 226 coupled to the antenna 122. The switch 218 enables time-division duplexing (TDD) for transmission and reception operations. Thus, the filter 216 is selectively coupled using the switch 218 to the power amplifier 206 for transmission operations and to the low-noise amplifier 212 for reception operations. Accordingly, a wireless signal 220 can be emanated from or received via the antenna 122.

For transmission operations, a transmission signal, which the filter 216 accepts from the power amplifier 206 via the directional coupler 130 and the switch 218, propagates through the filter 216. The filter 216 forwards a filtered transmission signal to the antenna 122 for emanation. For reception operations, a reception signal, which the filter 216 accepts from the antenna 122, propagates through the filter 216. The filter 216 forwards a filtered reception signal over the switch 218 to the low-noise amplifier 212. In other cases, the filter 216 can be implemented as a unidirectional filter or can be operated unidirectionally. Although TDD implementations are explicitly shown in FIG. 2 and described herein, the directional coupler 130 can alternatively or additionally be employed in frequency-division duplexing (FDD) implementations.

With regard to the transmission path, an output of the closed-loop controller 210 is coupled to an input of the power amplifier 206. An output of the power amplifier 206 is coupled to the first port 202-1 of the directional coupler 130. The directional coupler 130 forwards via the second port 202-2 the power amplifier output signal to the filter 216 via the switch 218. The third port 202-3 of the directional coupler 130 is coupled to an input of the feedback receiver 208, and an output of the feedback receiver 208 is coupled to a feedback input of the closed-loop controller 210. Thus, the directional coupler 130 can provide an indication of the output signal of the power amplifier 206 via the third port 202-3 to the feedback receiver 208. Although only certain components are explicitly depicted in FIG. 2 and are shown coupled together in a particular manner, a wireless interface device 120 or the RF front-end 128 thereof may include other non-illustrated components, more or fewer components, differently-coupled arrangements of components, and so forth.

The wireless interface device includes a feedback loop 204. The feedback loop 204, in an illustrated implementation, includes the closed-loop controller 210, the power amplifier 206, the directional coupler 130, and the feedback receiver 208. The wireless interface device uses the feedback loop 204 to implement one or more techniques to condition a signal so that a transmission operation meets some specified criterion. Examples of such techniques include transmit power control (TPC) to adhere to a wireless specification and/or increase efficiency, digital predistortion (DPD) to increase a linearity of the power amplification, and error vector magnitude (EVM) adjustment to decrease an EVM of a modulation constellation used for the transmission signal. The directional coupler 130 can facilitate these techniques by providing an accurate indication of the signal output by the power amplifier 206 while reducing an impact on the output signal.

With respect to the closed-loop controller 210, closed-loop power control compensates for changes in RF gain to ensure the proper root-mean-square (RMS) power is maintained. This can be a relatively slow moving control loop to adjust the baseband gain as the RF gain changes over frequency or temperature. As part of the compensation, the closed-loop controller 210 can alter a power of a transmission signal prior to providing the transmission signal to the power amplifier 206. To do so, the closed-loop controller 210 processes an indication of the output signal of the power amplifier 206 to determine how the power amplification is changing one or more characteristics of the transmission signal instantaneously or over time.

The closed-loop controller 210 therefore operates based on an indication of the output signal of the power amplifier 206. The directional coupler 130 accepts this output signal via the first port 202-1 thereof and couples an indication of this output signal from the third port 202-3 to an input of the feedback receiver 208. The feedback receiver 208 amplifies the signal indication and provides the amplified signal indication to the closed-loop controller 210. The closed-loop controller 210 performs signal manipulation (e.g., a power adjustment) based on the amplified signal indication. Accordingly, if the signal indication of the output signal deviates from the actual output signal of the power amplifier 206, the performance of the closed-loop controller 210 is degraded. A quality directional coupler 130 can therefore increase the accuracy of the closed-loop power control provided by the feedback loop 204. Analogous issues can impact DPD and EVM techniques and be partially remedied by a directional coupler 130 that provides an accurate indication of the output signal of the power amplifier 206.

Accordingly, implementing a quality directional coupler 130 can improve performance of the closed-loop controller 210. Additionally, a directional coupler 130 can be advantageously used in other areas of a wireless interface device 120, such as in the transceiver 126 or the communication processor 124. Moreover, a directional coupler 130 can be employed in other parts of an electronic device 102 (e.g., of FIG. 1) in which a signal is to be sampled.

The various portions of the wireless interface device can be realized with one or more PCBs. In some implementations, a single PCB can include the communication processor 124, the transceiver 126, and the RF front-end 128. In other implementations, one PCB may include the communication processor 124 and the transceiver 126, and another PCB may include the RF front-end 128. In still other implementations, one PCB may include the communication processor 124, and another PCB may include the transceiver 126 and the RF front-end 128. Alternatively, each of the communication processor 124, the transceiver 126, and the RF front-end 128 may be realized on a respective individual PCB.

Several interfaces between a component and a PCB are depicted in FIG. 2. For example, a first interface 224 can receive a power amplifier. As described above, a second interface 226 can couple an antenna, including an antenna module or an antenna feed, to the PCB. A third interface 228-1 or 228-2 can be coupled to a controller, such as the closed-loop controller 210. A fourth interface (not explicitly shown) can be coupled to the ground 222. Generally, an interface can include one or more pads, at least one receptacle for a pin, one or more mounting holes, and so forth to receive, accept, connect to, or couple to a chip, module, and the like.

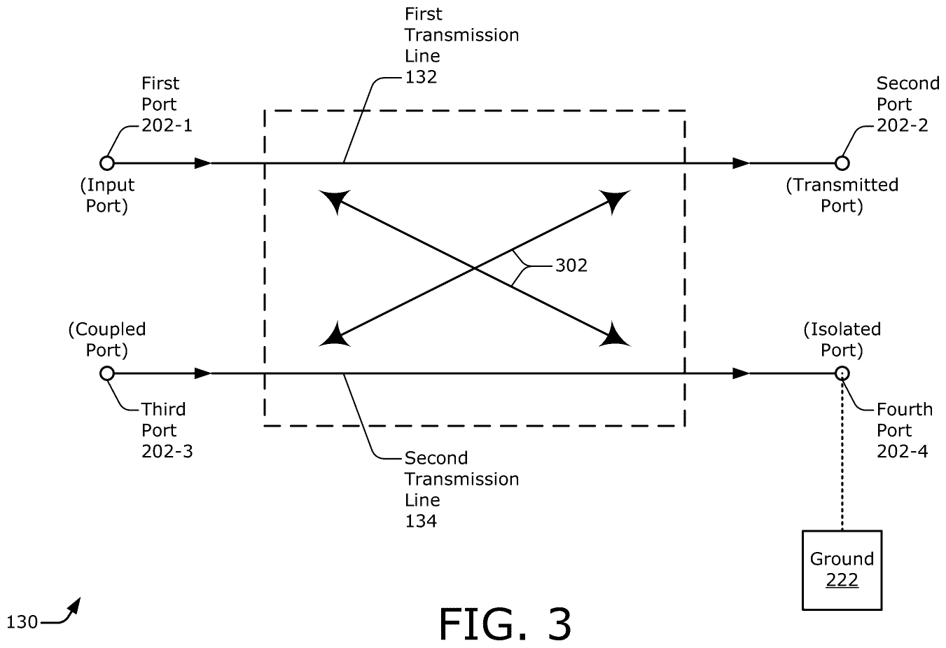

FIG. 3 illustrates an example directional coupler 130 with two transmission lines and four ports. As shown, the directional coupler 130 includes a first transmission line 132 and a second transmission line 134. The directional coupler 130 also includes four ports: a first port 202-1, a second port 202-2, a third port 202-3, and a fourth port 202-4. The first transmission line 132 is coupled between the first port 202-1 and the second port 202-2. The second transmission line 134 is coupled between the third port 202-3 and the fourth port 202-4. As represented by the crisscrossed arrows 302, the first transmission line 132 and the second transmission line 134 are electromagnetically coupled to each other. Thus, a first signal propagating along the first transmission line 132 can generate a related, second signal in the second transmission line 134 that samples the first signal.

In example implementations, the directional coupler 130 is coupled between two nodes that are propagating a signal. For instance, a stripline or microstrip transmission line that is propagating an amplified signal output by a power amplifier toward an antenna can realize the first transmission line 132. In cases in which the first transmission line 132 is propagating an “active” or “independent” signal, the first transmission line 132 can correspond to a main transmission line. Thus, in such cases, the second transmission line 134 can correspond to a coupled transmission line that is producing a “sampled” or “dependent” signal.

Further, the first port 202-1 can correspond to an input port of the directional coupler 130, and the second port 202-2 can correspond to a transmitted port of the directional coupler 130. The third port 202-3 can correspond to a coupled port of the directional coupler 130, and the fourth port 202-4 can correspond to an isolated port of the directional coupler 130. Example connections for the first through third ports 202-1 to 202-3 are illustrated in FIG. 2 and described above. In some implementations, the fourth port 202-4 can be coupled to a ground 222, which may be in a different layer than that of the directional coupler 130.

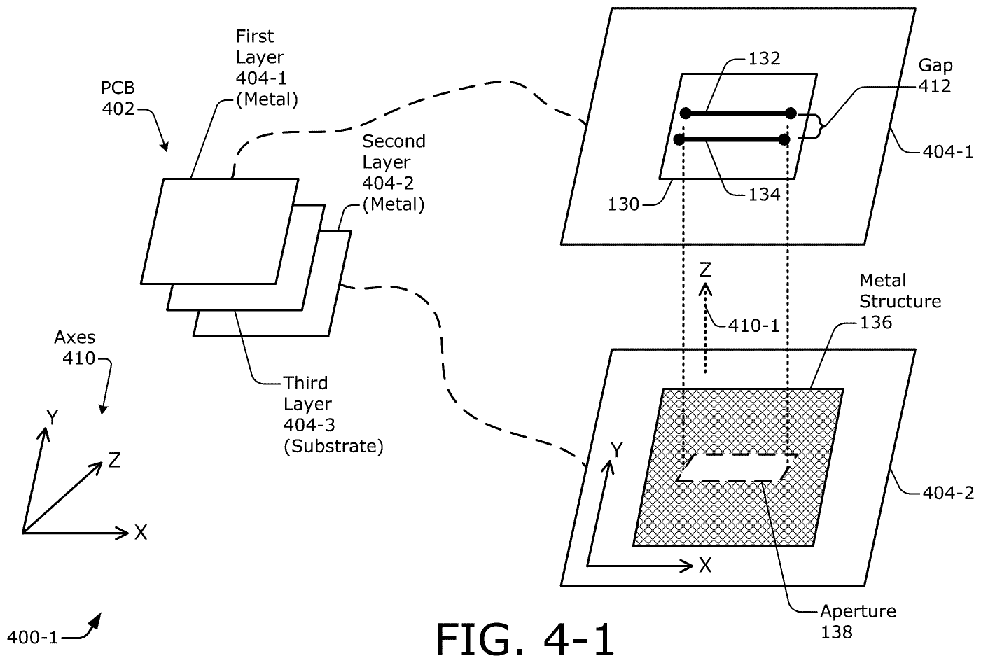

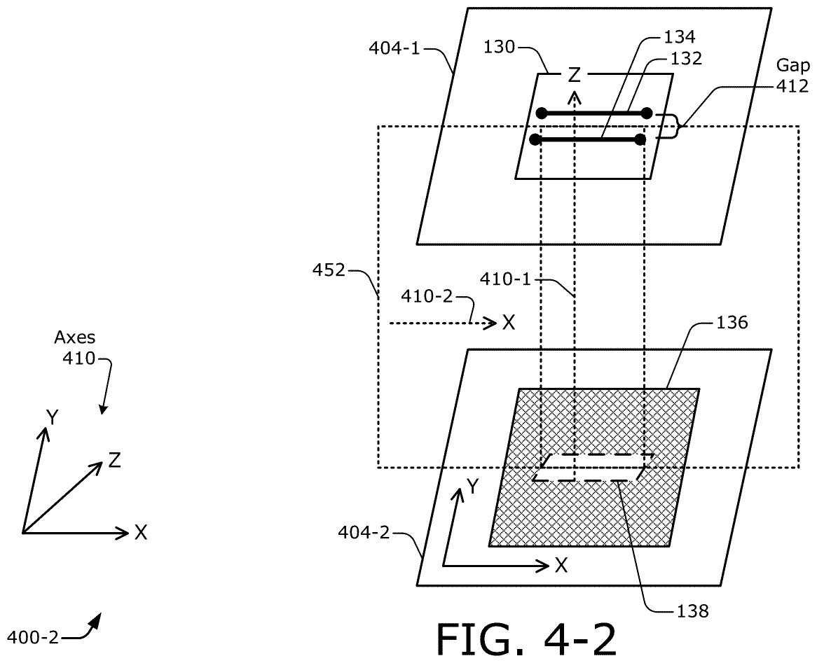

FIG. 4-1 is an exploded diagram 400-1 of an example PCB 402 that includes multiple layers 404-1 to 404-3 in which a directional coupler 130 and an associated ground structure can be implemented. Three axes 410 (e.g., an axis 410-1, 410-2, and 410-3) are depicted to indicate orthogonal directions in the “X,” “Y,” and “Z” directions. As shown, the PCB 402 includes three layers 404-1 to 404-3. The PCB can, however, include more or fewer layers. In some cases with multilayer PCBs, fabrication equipment can laminate alternating layers of prepreg and core materials.

In example implementations, as depicted on the left, the PCB 402 includes a first layer 404-1, a second layer 404-2, and a third layer 404-3. The first layer 404-1 comprises a metal (e.g., copper) layer, and the second layer 404-2 comprises another metal layer. The third layer 404-3 comprises a substrate, such as a dielectric or insulator (e.g., a pre-impregnated fiberglass bonding material or fiberglass (FR4)). The substrate can insulate one metal layer from another metal layer, provide physical support for metal and other layer(s), and so forth. Each layer 404 can be substantially parallel to each other layer of the multiple layers of the PCB. For example, each layer can be as parallel as standard PCB fabrication techniques permit. For instance, each layer may be within 10%, 5%, or even 1%, of being parallel to another layer. In some cases, each layer can lie within a respective plane of its own that does not intersect another plane corresponding to another layer, at least for a rigid PCB.

As depicted on the right of FIG. 4-1, the first layer 404-1 includes a directional coupler 130. The directional coupler 130 includes a first transmission line 132 and a second transmission line 134. In operation, the second transmission line 134 is electromagnetically coupled to the first transmission line 132. The second transmission line 134 is spaced apart from the first transmission line 132 to form a gap 412 in the first layer 404-1 between the first transmission line 132 and the second transmission line 134. The gap 412 may have a uniform width or may have different widths across its length. In some cases, as shown in FIGS. 5-1 to 6-4, the second transmission line 134 includes at least one bend.

The second layer 404-2 includes a metal structure 136. The metal structure 136 includes an aperture 138. The aperture 138 can be positioned such that an axis (e.g., the Z-axis 410-1) that is substantially perpendicular to the second layer 404-2 extends through the gap 412 at the first layer 404-1 and the aperture 138 at the second layer 404-2. This axis (e.g., the Z-axis 410-1) can also be substantially perpendicular to the first layer 404-1. The metal structure 136 can provide a ground for at least the first transmission line 132. Further, the metal structure 136 can provide a ground for the second transmission line 134. Generally, the metal structure 136 can form at least part of a ground plane for at least part of at least one other layer of the PCB 402, such as for the circuitry of the first layer 404-1.

FIG. 4-2 is an exploded diagram 400-2 of a PCB 402 (e.g., of FIG. 4-1) including a first layer 404-1 with a directional coupler 130 and a second layer 404-2 with a metal structure 136 having an aperture 138. The exploded diagram 400-2 illustrates a relative spatial relationship between the first layer 404-1 and the second layer 404-2. More specifically, the exploded diagram 400-2 illustrates a relative spatial relationship between the gap 412 of the directional coupler 130 in the first layer 404-1 and the aperture 138 of the metal structure 136 in the second layer 404-2. For example, the aperture 138 can at least partially overlap the gap 412. Similarly, the gap 412 can at least partially overlap the aperture 138.

More specifically, in some implementations, a plane 452 that contains the axis (e.g., the Z-axis 410-1), which is substantially perpendicular to the second layer 404-2, is substantially perpendicular to the first layer 404-1 and the second layer 404-2. The plane 452 extends through the aperture 138 in a first dimension (e.g., along the Z-axis 410-1) of the plane 452. The plane 452 also extends along a length of the aperture 138 in a second dimension (e.g., along the X-axis 410-2) of the plane 452. Further, the plane 452 avoids intersecting the first transmission line 132 and the second transmission line 134.

As described below and depicted more clearly in FIGS. 5-1 to 5-3 and 6-1 to 6-4, a directional coupler 130 can include coupled lines in which the coupled transmission line is meandered to make the design compact in size (e.g., occupying a smaller area). A meandered transmission line, however, creates edge couplings and bend couplings. These couplings degrade the return losses of the ports and the coupling factor. The degraded coupling factor in turn degrades the directivity of the directional coupler, and directivity affects a quality of the directional coupler. Generally, a relationship between directivity and coupling factor for a directional coupler can be given by the following equation: Directivity=Isolation−Coupling Factor.

Another challenge, besides size, is to achieve a target coupling factor across a particular frequency range (e.g., 4.5 to 7.5 GHZ). In some cases, the two transmission lines of a directional coupler—absent employment of the principles described herein—would be placed relatively close to each other to achieve the target coupling factor. For instance, the two transmission lines would be disposed at a spacing of 0.01 millimeters (mm), which is impractical, if not impossible, to fabricate on a PCB.

To achieve the target coupling factor without relying on a 0.1-mm-spacing between the two transmission lines, described implementations create an aperture (e.g., a slot) in an associated metal structure (e.g., a ground plane) underneath the transmission lines. The aperture increases the impedance between the spacing, thus decreasing the coupling factor without needing to fabricate an overly narrow spacing between the coupled transmission lines. For example, in some cases, using an aperture in an underlying metal structure can achieve the target coupling factor with a spacing (or gap) of 0.25 mm—a twenty-five-fold greater permitted spacing between the two transmission lines. By reducing the coupling factor, the aperture can increase the directivity of the directional coupler, in accordance with the equation set forth above. Thus, an aperture in the associated metal structure can provide a mechanism for increasing a directivity of the directional coupler by reducing a coupling factor thereof.

Further, in some implementations, a shape of the aperture in the associated metal structure can be tailored to favor a reduction of the edge and bend couplings in the meandered transmission line. Reducing these couplings can improve port return losses and isolation between ports of the directional coupler and facilitate achieving a target coupling factor across a given band.

FIGS. 5-1 to 5-3 are schematic diagrams 500-1 to 500-3, respectively, of an example directional coupler 130 with a first transmission line 132 and a second transmission line 134 that meanders in conjunction with three respective example implementations of an associated aperture 138. Each diagram also depicts four ports: a first port 202-1, a second port 202-2, a third port 202-3, and a fourth port 202-4. These diagrams are not necessarily drawn to scale. For example, the transmission lines are illustrated as relatively thin lines without internal, or width, dimensionality.

In example implementations, the second transmission line 134 is fabricated as a meandered transmission line (or meander transmission line or meandering transmission line). As shown, the second transmission line 134 includes multiple bends. The depicted meandered transmission line includes at least three bends, but it may include more or fewer bends. Each bend 504 (or bend coupling 504) of the illustrated bends is approximately ninety degrees (90°). For example, each bend 504 can be within 10%, within 5%, or even within 2%, of ninety degrees. In other implementations, however, the bends can have different angles, such as forty-five degrees (45°), sixty degrees (60°), 120°. 135°, 180°, and so forth.

The schematic diagram 500-1 also depicts at least one gap 412 between the first transmission line 132 and the second transmission line 134. The gap 412 has at least one width 502. With a transmission line of the directional coupler 130 being meandered, the gap 412 can have multiple widths: a first width 502-1 and a second width 502-2. The first width 502-1 is between the first transmission line 132 and an edge coupling 506-1 of the second transmission line 134 that is relatively more proximate to the first transmission line 132. The second width 502-2 is between the first transmission line 132 and an edge coupling 506-2 of the second transmission line 134 that is relatively more distant from the first transmission line 132. Accordingly, the second width 502-2 is greater than the first width 502-1.

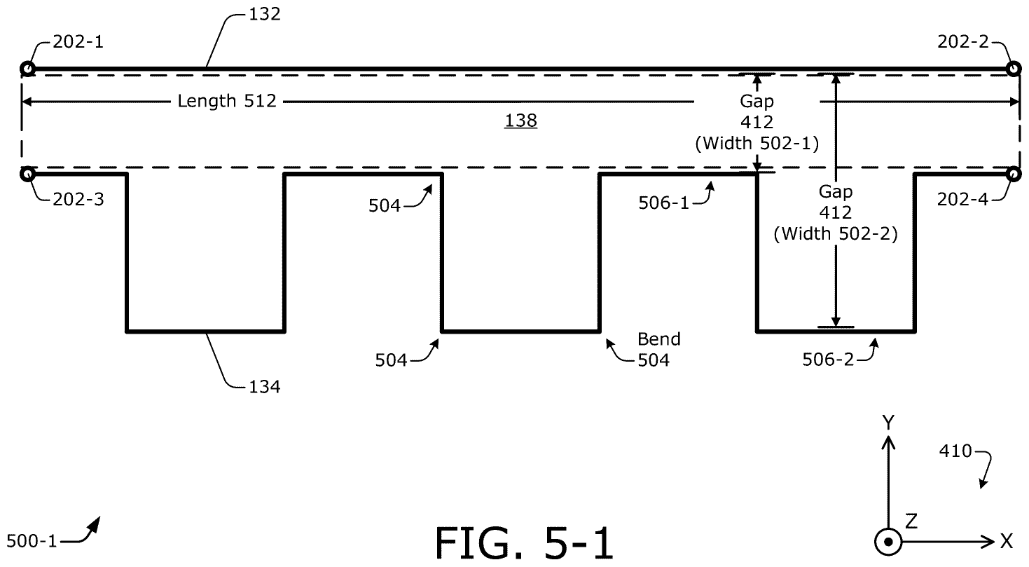

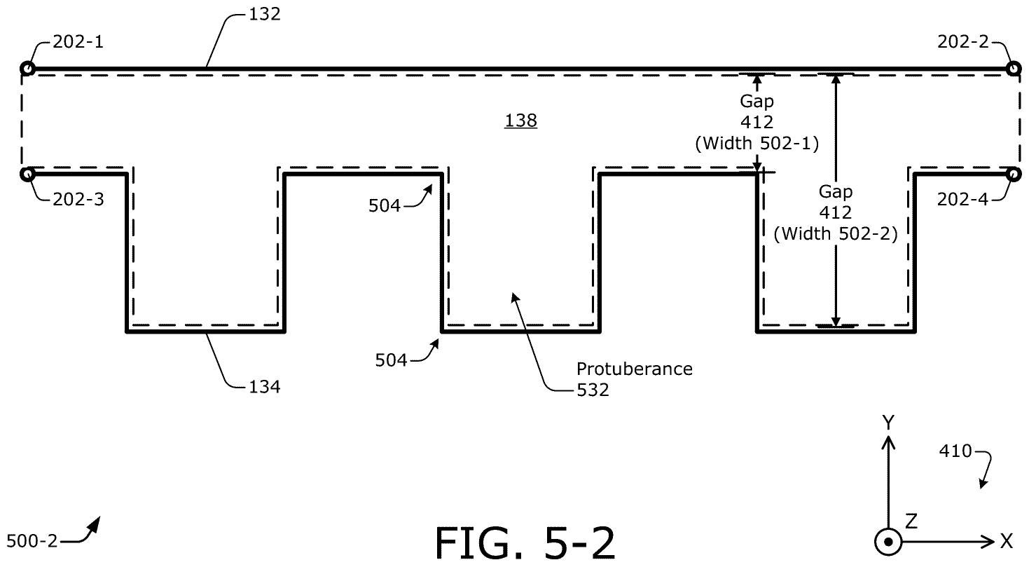

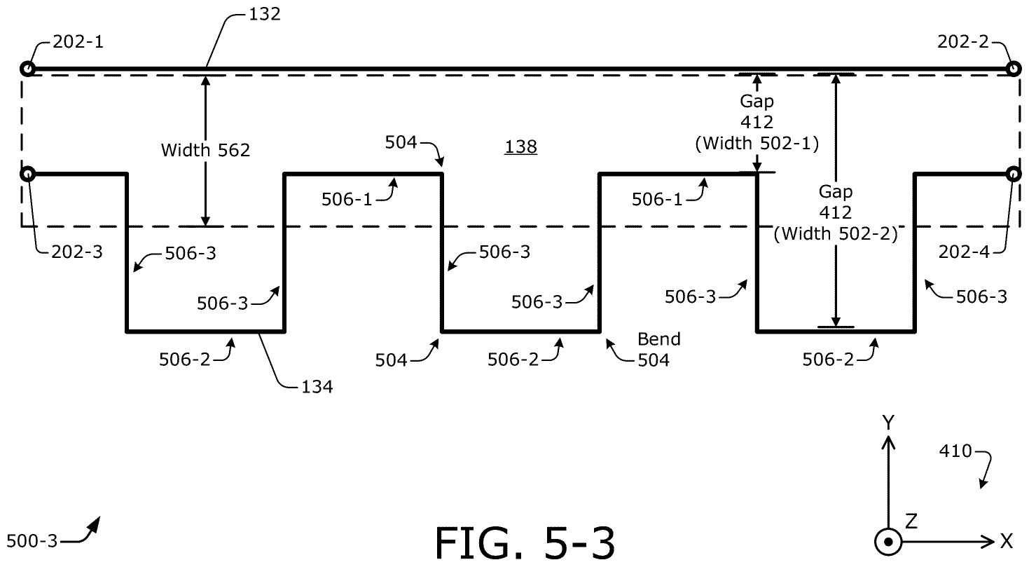

In the schematic diagrams 500-1 to 500-3 of FIGS. 5-1 to 5-3, the aperture 138 is depicted as being “under” the directional coupler 130 as indicated by the axes 410 and the long-dashed lines representing a boundary of the aperture 138. In example implementations, the aperture 138 at least partially overlaps the gap 412, has a length 512 that is substantially the same as a length of the first transmission line 132, and has a single width that substantially matches the first width 502-1 of the gap 412. Thus, in the example of FIG. 5-1, the aperture 138 substantially overlaps the first width 502-1 of the gap 412. However, the aperture 138 substantially avoids overlapping the first transmission line 132 and the second transmission line 134, and thus substantially avoids the second width 502-2 potion of the gap 412. In this context, substantially avoiding an overlap can correspond to no overlap and up to 1% overlap, 5% overlap, or even 10% overlap. Similarly, one aspect substantially overlapping another aspect can correspond to complete overlap or down to 99% overlap, 95% overlap, or even 90% overlap.

Turning to the schematic diagram 500-2 of FIG. 5-2, the gap 412 has the first width 502-1 and the second width 502-2. In these example implementations, however, the aperture 138 is shaped to follow; track, or adhere to these multiple widths. The aperture 138 has at least one protuberance 532 (e.g., three as depicted in FIG. 5-2) that extends from a slot-shaped portion of the aperture 138 at various distances lengthwise along the gap 412. Thus, the aperture 138 in FIG. 5-2 has multiple widths that are substantially the same as the multiple widths of the gap 412. In this case, the aperture 138 substantially avoids overlapping the first transmission line 132 and the second transmission line 134, but the aperture 138 does substantially overlap the first and second widths 502-1 and 502-2 of the gap 412. In this context, substantially avoiding an overlap can correspond to no overlap and up to 1% overlap, 5% overlap, or even 10% overlap. Conversely, substantially overlapping can correspond to complete overlap or to being within 1%, 5%, or even 10% of an edge of a transmission line, in either direction from the edge—overlapping or not overlapping.

Turning to the schematic diagram 500-3 of FIG. 5-3, the gap 412 has the first width 502-1 and the second width 502-2. In these example implementations, the aperture 138 has a single width 562. This width 562 is greater than the first width 502-1 of the gap 412 but less than the second width 502-2 of the gap 412. As shown, the aperture 138 substantially avoids overlapping the first transmission line 132. In contrast, the aperture 138 at least partially overlaps the second transmission line 134. For example, the multiple edge couplings (e.g., an edge coupling 506-1) of the second transmission line 134 that are parallel with and more proximate to the first transmission line 132 overlap with the aperture 138. But the multiple edge couplings (e.g., an edge coupling 506-2) of the second transmission line 134 that are parallel with and more distant from the first transmission line 132 do not overlap with the aperture 138. Further, the multiple edge couplings (e.g., an edge coupling 506-3) of the second transmission line 134 that are perpendicular to the first transmission line 132 partially overlap with the aperture 138 and partially do not overlap with the aperture 138.

The three implementations of apertures with different widths and shapes across FIGS. 5-1 to 5-2 are presented by way of example only. Other apertures can have different widths, lengths, or shapes. For example, a length 512 of an aperture 138 may be longer or shorter than a length of the first transmission line 132. Additionally or alternatively, an aperture 138 may have a different quantity of protuberances than a gap 412 has “dips” with a greater second width 502-2. Further, an aperture 138 may have protuberances and at least partially overlap the second transmission line 134, examples of which are described below and depicted with reference to FIGS. 6-1 to 6-4.

FIGS. 6-1 to 6-4 are schematic diagrams 600-1 to 600-4, respectively, of different views and aspects of an example directional coupler 130 with a first transmission line 132 and a second transmission line 134, which meanders, in conjunction with an associated example aperture 138. As shown in diagram 600-1, the directional coupler 130 can include four ports: a first port 202-1, a second port 202-2, a third port 202-3, and a fourth port 202-4. These diagrams are not necessarily drawn to scale, but the transmission lines are illustrated with a width or dimensionality.

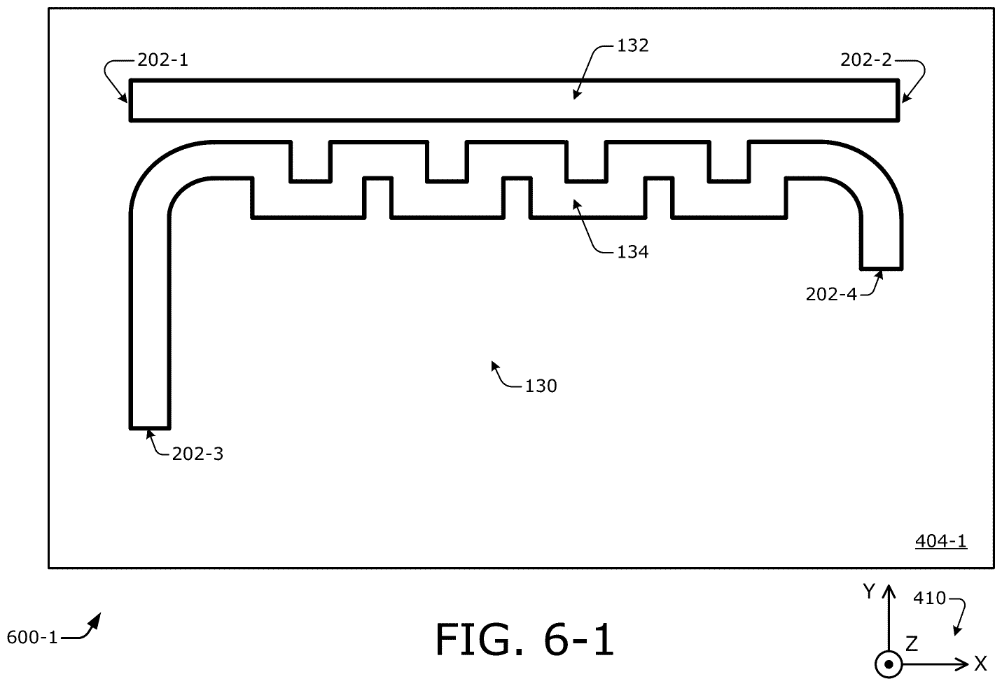

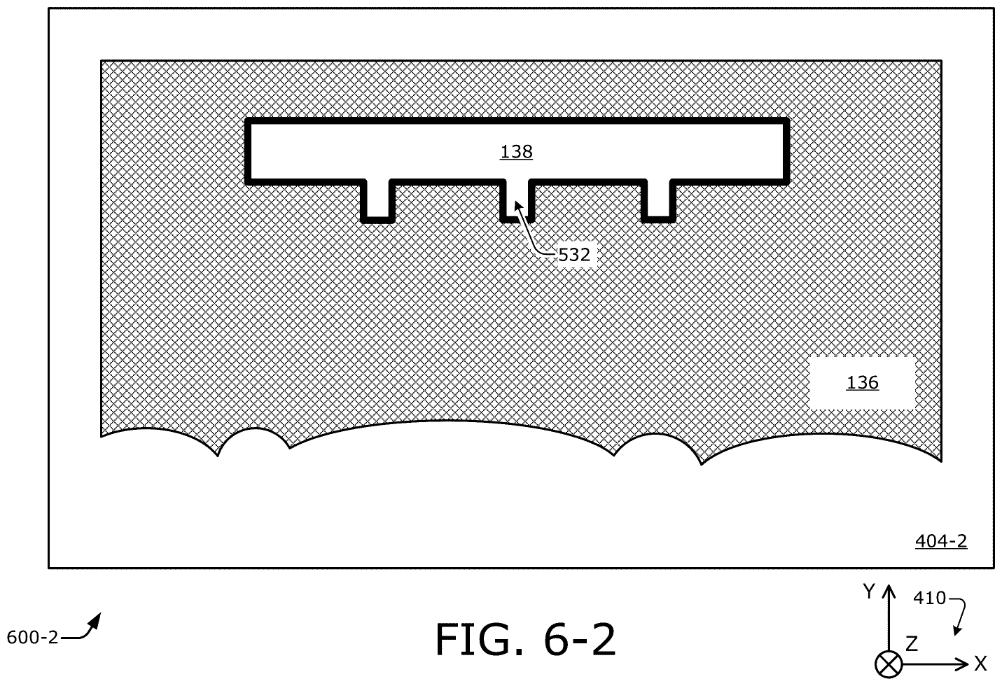

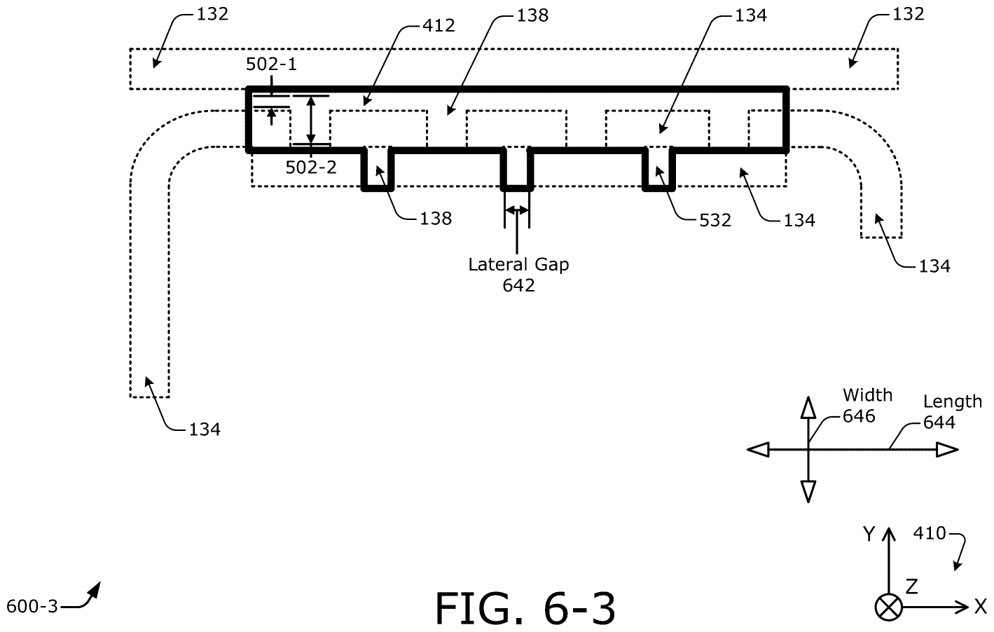

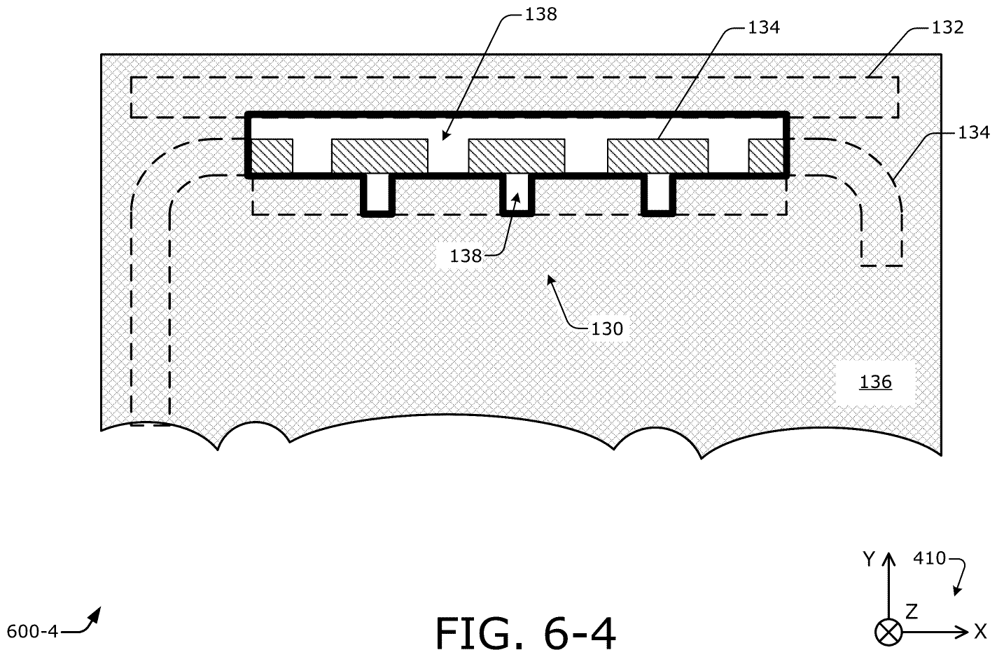

FIG. 6-1 is a schematic diagram 600-1 of an example directional coupler 130 with a first transmission line 132 and a second transmission line 134 that meanders. FIG. 6-1 depicts a “top” view of the PCB 402 (of FIG. 4-1) that shows the first layer 404-1 as indicated by the axes 410 (e.g., the “Z” axis is coming out of the drawing). The second transmission line 134 includes multiple bends, such as sixteen (16) bends. The second transmission line 134 can, however, have more or fewer bends. The bends are illustrated as ninety-degree (90°)bends with hard, or sharp, corners. Multiple bends can alternatively or additionally have different angles or have rounded corners. Further, different bends can have diverging characteristics within a given second transmission line 134. For example, two bends may have soft, 180° Corners, and other bends of the same meandered coupled transmission line may have hard, 135° Corners.

FIG. 6-2 is a schematic diagram 600-2 of an example metal structure 136 having an aperture 138 that can be spatially mated to, or aligned with, the directional coupler 130 of FIG. 6-1. FIG. 6-2 depicts a “bottom” view of the PCB 402 (of FIG. 4-1) that shows the second layer 404-2 as indicated by the axes 410 (e.g., the “Z” axis is going into the drawing). The metal structure 136, which is indicated with a cross-hatched pattern, defines or forms the aperture 138. The metal structure 136 can extend farther from the aperture 138 than is shown, or the metal structure 136 may have external edges that are closer to the edges of the aperture 138 than is shown. The metal structure 136 may also have a different external shape. As shown, the aperture 138 can be substantially slot-shaped, such as by being rectangular with sharp or rounded corners. The aperture 138 can also have at least one protuberance 532. In other implementations, the shape of the aperture 138 can be different (e.g., elliptical or a non-regular polygon) and can have more or fewer protuberances (including no protuberances).

FIG. 6-3 is a schematic diagram 600-3 of the example aperture 138 of FIG. 6-2 superimposed over the example directional coupler 130 of FIG. 6-1 in an example relative spatial arrangement. FIG. 6-3 depicts a “bottom” view of the PCB 402 (of FIG. 4-1) that shows the aperture 138 “on top” of the directional coupler 130, which is indicated by the axes 410 and the small-dashed lines illustrating the directional coupler 130. For clarity, two lines with double arrows indicate an example length direction (length 644) versus an example width direction (width 646). In the illustrated example, the first transmission line 132 has a length and a width, with the length being greater than the width. The aperture 138 has a length and a width, with the length of the aperture 138 being greater than the width of the aperture 138. Further, the length of the aperture 138 is substantially equal to the length of the first transmission line 132, and the width of the aperture 138 is greater than the width of the first transmission line 132.

In the depicted example alignment, the aperture 138 substantially overlaps the gap 412 between the two transmission lines at the first width 502-1 and the second width 502-2. Further, the aperture 138 substantially overlaps the lower lateral gaps between adjacent edge couplings of the second transmission line 134 that are relatively farther from the first transmission line 132. To do so, the aperture 138 includes a respective protuberance 532 for each respective lateral gap 642. This size, shape, and overlapping alignment of the aperture 138 results in some of the second transmission line 134 overlapping the aperture 138, and vice versa. This overlapping is shown more clearly in FIG. 6-4.

FIG. 6-4 is a schematic diagram 600-4 of the example aperture 138 of FIG. 6-2, in conjunction with the corresponding metal structure 136, layered over the example directional coupler 130 of FIG. 6-1. FIG. 6-4 depicts a “bottom” view of the PCB 402 (of FIG. 4-1) that shows the metal structure 136, including the aperture 138, “on top” of the directional coupler 130, which is indicated by the axes 410 and the large-dashed lines illustrating the directional coupler 130 “under” the metal structure 136. The metal structure 136, which is indicated with a cross-hatched fill pattern, defines or forms the aperture 138. The metal portions of the directional coupler 130 that are visible in this view are indicated by the diagonal-line fill pattern. It is therefore apparent which portions of the directional coupler 130 do not overlap the metal structure 136. It is also apparent which portions of the directional coupler 130 overlap the aperture 138 (e.g., the portions with the diagonal-line fill pattern) and which portions of the directional coupler 130 do not overlap the aperture 138 (e.g., the portions indicated by the dashed-line outline).

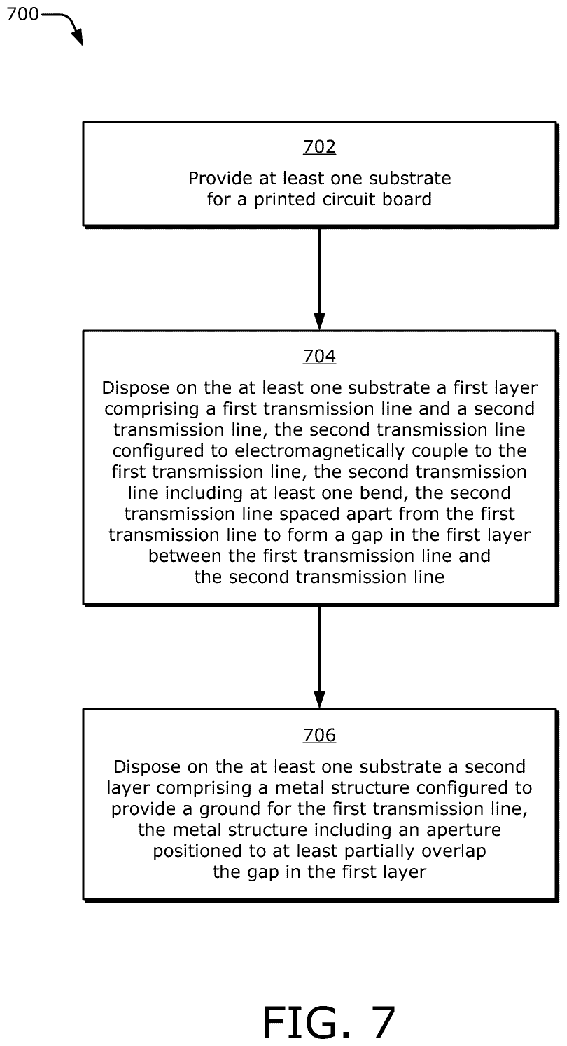

FIG. 7 is a flow diagram illustrating an example process 700 for manufacturing a directional coupler and associated ground structure. The process 700 includes three blocks 702-706 that specify operations that can be performed for a method. The process is described in the form of a set of blocks that specify operations that can be performed. However, operations are not necessarily limited to the order shown in the figures or described herein, for the operations may be implemented in alternative orders or in fully or partially overlapping manners. Also, more, fewer, and/or different operations may be implemented to perform a respective process or an alternative process.

At block 702, at least one substrate for a printed circuit board is provided. For example, fabrication equipment can provide at least one substrate (e.g., of a third layer 404-3) for a printed circuit board 402. The substrate may be, for instance, an insulator or support structure such as fiberglass (FR4) having a 0.115 mm thickness.

At block 704, a first layer comprising a first transmission line and a second transmission line is disposed on the at least one substrate, with the second transmission line configured to electromagnetically couple to the first transmission line. The second transmission line includes at least one bend, and the second transmission line is spaced apart from the first transmission line to form a gap in the first layer between the first transmission line and the second transmission line. For example, the fabrication equipment can dispose on the at least one substrate (e.g., of the third layer 404-3) a first layer 404-1 comprising a first transmission line 132 and a second transmission line 134, with the second transmission line 134 configured to electromagnetically couple to the first transmission line 132. The second transmission line 134 includes at least one bend 504, and the second transmission line 134 is spaced apart from the first transmission line 132 to form a gap 412 in the first layer 404-1 between the first transmission line 132 and the second transmission line 134. In some cases, the gap 412 may have multiple widths (e.g., a first width 502-1 and a second width 502-2) based on given edge couplings 506-1 and 506-2 of the second transmission line 134 having different distances to the first transmission line 132.

At block 706, a second layer comprising a metal structure configured to provide a ground for the first transmission line is disposed on the at least one substrate, with the metal structure including an aperture positioned to at least partially overlap the gap in the first layer. For example, the fabrication equipment can dispose on the at least one substrate (e.g., of the third layer 404-3) a second layer 404-2 comprising a metal structure 136 configured to provide a ground 222 for the first transmission line 132. The metal structure 136 includes an aperture 138 positioned to at least partially overlap the gap 412 in the first layer 404-1. The aperture 138 may fully or partially overlap the gap 412, or vice versa, to reduce the coupling factor of the directional coupler 130 and thereby increase the directivity thereof. The metal structure 136 may also function as a ground for the second transmission line 134 or generally as a ground plane for the first layer 404-1. In some cases, the aperture 138 of the metal structure 136 may be positioned such that an axis (e.g., the “Z” axis 410-1) that is substantially perpendicular to the second layer 404-2 extends through the gap 412 in the first layer 404-1 and the aperture 138 in the second layer 404-2.

### Implementation Examples

This section describes some aspects of example implementations and/or example configurations related to the apparatuses and/or processes presented above.

Example aspect 1: An apparatus comprising:
a printed circuit board comprising:
   a first layer comprising:
      a first transmission line; and
      a second transmission line configured to electromagnetically couple to the first transmission line, the second transmission line including at least one bend, the second transmission line spaced apart from the first transmission line to form a gap in the first layer between the first transmission line and the second transmission line; and
   a second layer comprising a metal structure configured to provide a ground for the first transmission line, the metal structure including an aperture positioned to at least partially overlap the gap in the first layer.

Example aspect 2: The apparatus of example aspect 1, wherein:
the second transmission line comprises a meandered transmission line.

Example aspect 3: The apparatus of example aspect 1 or 2, wherein:
the second transmission line includes at least three bends.

Example aspect 4: The apparatus of example aspect 3, wherein:
each bend of the at least three bends is approximately ninety degrees (90°).

Example aspect 5: The apparatus of any one of the preceding example aspects, wherein:
the aperture of the metal structure in the second layer is positioned such that an axis that is substantially perpendicular to the second layer extends through the gap and the aperture.

Example aspect 6: The apparatus of example aspect 5, wherein:
a plane that contains the axis is substantially perpendicular to the first layer and the second layer;
the plane extends through the aperture in a first dimension of the plane, and the plane extends along a length of the aperture in a second dimension of the plane; and
the plane avoids intersecting the first transmission line and the second transmission line.

Example aspect 7: The apparatus of any one of the preceding example aspects, wherein:
the first transmission line has a length and a width, the length being greater than the width;
the aperture has a length and a width, the length of the aperture being greater than the width of the aperture;
the length of the aperture is substantially equal to the length of the first transmission line; and
the width of the aperture is greater than the width of the first transmission line.

Example aspect 8: The apparatus of any one of the preceding example aspects, wherein:
the aperture has a slot shape.

Example aspect 9: The apparatus of example aspect 8, wherein:
the aperture has at least one protuberance extending from the slot shape toward the second transmission line.

Example aspect 10: The apparatus of example aspect 8 or 9, wherein:
the first transmission line substantially avoids overlapping the slot shape of the aperture; and
the second transmission line at least partially overlaps the slot shape of the aperture.

Example aspect 11: The apparatus of any one of the preceding example aspects, wherein:
the printed circuit board comprises a third layer comprising a substrate disposed between the first layer and the second layer; and
the third layer is substantially parallel to the first layer and the second layer.

Example aspect 12: The apparatus of any one of the preceding example aspects, wherein:
the metal structure comprises a ground plane relative to the first transmission line, the second transmission line, and other circuitry disposed on the first layer.

Example aspect 13: The apparatus of any one of the preceding example aspects, wherein:
the metal structure is configured to provide the ground for the second transmission line.

Example aspect 14: The apparatus of any one of the preceding example aspects, wherein:
the first transmission line and the second transmission line comprise a directional coupler disposed in the first layer.

Example aspect 15: The apparatus of any one of the preceding example aspects, wherein:
the first transmission line is coupled between a first interface configured to receive a power amplifier and a second interface configured to be coupled to an antenna.

Example aspect 16: The apparatus of any one of the preceding example aspects, wherein:
the second transmission line is coupled between a third interface configured to be coupled to a controller and a fourth interface coupled to the ground.

Example aspect 17: The apparatus of any one of example aspects 14-16, further comprising:
a radio-frequency front-end coupled to the printed circuit board, the radio-frequency front-end comprising the directional coupler; and
at least one processor operatively coupled to the radio-frequency front-end, the at least one processor configured to coordinate transmission of one or more wireless signals using the directional coupler of the radio-frequency front-end.

Example aspect 18: An apparatus for electromagnetic coupling, the apparatus comprising:
a directional coupler comprising:
   a main transmission line disposed in a first layer of a printed circuit board; and
   a meandered transmission line disposed in the first layer of the printed circuit board, the meandered transmission line configured to electromagnetically couple to the main transmission line, the meandered transmission line spaced apart from the main transmission line to form a gap in the first layer between the main transmission line and the meandered transmission line; and
a metal structure disposed in a second layer of the printed circuit board, the metal structure comprising means for increasing a directivity of the directional coupler by reducing a coupling factor.

Example aspect 19: The apparatus of example aspect 18, wherein:
the metal structure is configured to provide a ground for the main transmission line and the meandered transmission line.

Example aspect 20: A method of manufacturing a printed circuit board, the method comprising:
providing at least one substrate for the printed circuit board;
disposing on the at least one substrate a first layer comprising a first transmission line and a second transmission line, the second transmission line configured to electromagnetically couple to the first transmission line, the second transmission line including at least one bend, the second transmission line spaced apart from the first transmission line to form a gap in the first layer between the first transmission line and the second transmission line; and
disposing on the at least one substrate a second layer comprising a metal structure configured to provide a ground for the first transmission line, the metal structure including an aperture positioned to at least partially overlap the gap in the first layer.

### Conclusion

As used herein, the terms “couple,” “coupled,” or “coupling” refer to a relationship between two or more components that are in operative communication with each other to implement some feature or realize some capability that is described herein. The coupling can be realized using, for instance, a physical line, such as a metal trace or wire, or an electromagnetic coupling, such as with a transformer. A coupling can include a direct coupling or an indirect coupling. A direct coupling refers to connecting discrete circuit elements via a same node without an intervening element. An indirect coupling refers to connecting discrete circuit elements via one or more other devices or other discrete circuit elements, including two or more different nodes.

The term “node” (e.g., including a “first node” or a “local oscillator node”) represents at least a point of electrical connection between two or more components (e.g., circuit elements). Although at times a node may be visually depicted in a drawing as a single point, the node can represent a connection portion of a physical circuit or network that has approximately a same voltage potential at or along the connection portion between two or more components. In other words, a node can represent at least one of multiple points along a conducting medium (e.g., a wire or trace) that exists between electrically connected components. Similarly, a “terminal” or “port” may represent one or more points with at least approximately a same voltage potential relative to an input or output of a component (e.g., a directional coupler).

The terms “first,” “second,” “third,” and other numeric-related indicators are used herein to identify or distinguish similar or analogous items from one another within a given context-such as a particular implementation, a single drawing figure, a given component, or a claim. Thus, a first item in one context may differ from a first item in another context. For example, an item identified as a “first port” in one context may be identified as a “second port” in another context. Similarly, a “first transmission line” or a “first dimension” in one claim may be recited as a “second transmission line” or a “third dimension,” respectively, in a different claim (e.g., in separate claim sets). An analogous interpretation applies to differential-related terms such as a “plus resistor” and a “minus resistor.”

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for a directional coupler and associated ground structure have been described in language specific to certain features and/or methods, the subject of the appended claims is not necessarily limited to the specific features or methods described. Rather, the specific features and methods are disclosed as example implementations for a directional coupler and associated ground structure.

What is claimed is:

1. An apparatus comprising:
a printed circuit board comprising:
a first layer comprising:
a first transmission line; and
a second transmission line configured to electromagnetically couple to the first transmission line, the second transmission line including at least one bend, the second transmission line spaced apart from the first transmission line to form a gap in the first layer between the first transmission line and the second transmission line; and
a second layer comprising a metal structure configured to provide a ground for the first transmission line, the metal structure including an aperture positioned to at least partially overlap the gap in the first layer.

2. The apparatus of claim 1, wherein:
the second transmission line comprises a meandered transmission line.

3. The apparatus of claim 2, wherein:
the second transmission line includes at least three bends.

4. The apparatus of claim 3, wherein:
each bend of the at least three bends is approximately ninety degrees (90°).

5. The apparatus of claim 1, wherein:
the aperture of the metal structure in the second layer is positioned such that an axis that is substantially perpendicular to the second layer extends through the gap and the aperture.

6. The apparatus of claim 5, wherein:
a plane that contains the axis is substantially perpendicular to the first layer and the second layer;
the plane extends through the aperture in a first dimension of the plane, and the plane extends along a length of the aperture in a second dimension of the plane; and
the plane avoids intersecting the first transmission line and the second transmission line.

7. The apparatus of claim 1, wherein:
the first transmission line has a length and a width, the length being greater than the width;
the aperture has a length and a width, the length of the aperture being greater than the width of the aperture;
the length of the aperture is substantially equal to the length of the first transmission line; and
the width of the aperture is greater than the width of the first transmission line.

8. The apparatus of claim 1, wherein:
the aperture has a slot shape.

9. The apparatus of claim 8, wherein:
the aperture has at least one protuberance extending from the slot shape toward the second transmission line.

10. The apparatus of claim 8, wherein:
the first transmission line substantially avoids overlapping the slot shape of the aperture; and
the second transmission line at least partially overlaps the slot shape of the aperture.

11. The apparatus of claim 1, wherein:
the printed circuit board comprises a third layer comprising a substrate disposed between the first layer and the second layer; and
the third layer is substantially parallel to the first layer and the second layer.

12. The apparatus of claim 11, wherein:
the metal structure comprises a ground plane relative to the first transmission line, the second transmission line, and other circuitry disposed on the first layer.

13. The apparatus of claim 1, wherein:
the metal structure is configured to provide the ground for the second transmission line.

14. The apparatus of claim 1, wherein:
the first transmission line and the second transmission line comprise a directional coupler disposed in the first layer.

15. The apparatus of claim 14, wherein:
the first transmission line is coupled between a first interface configured to receive a power amplifier and a second interface configured to be coupled to an antenna.

16. The apparatus of claim 15, wherein:
the second transmission line is coupled between a third interface configured to be coupled to a controller and a fourth interface coupled to the ground.

17. The apparatus of claim 16, further comprising:
a radio-frequency front-end coupled to the printed circuit board, the radio-frequency front-end comprising the directional coupler; and
at least one processor operatively coupled to the radio-frequency front-end, the at least one processor configured to coordinate transmission of one or more wireless signals using the directional coupler of the radio-frequency front-end.

18. An apparatus for electromagnetic coupling, the apparatus comprising:
a directional coupler comprising:
a main transmission line disposed in a first layer of a printed circuit board; and
a meandered transmission line disposed in the first layer of the printed circuit board, the meandered transmission line configured to electromagnetically couple to the main transmission line, the meandered transmission line spaced apart from the main transmission line to form a gap in the first layer between the main transmission line and the meandered transmission line; and
a metal structure disposed in a second layer of the printed circuit board, the metal structure comprising means for increasing a directivity of the directional coupler by reducing a coupling factor.

19. The apparatus of claim 18, wherein;
the metal structure is configured to provide a ground for the main transmission line and the meandered transmission line.

20. A method of manufacturing a printed circuit board, the method comprising:
providing at least one substrate for the printed circuit board;
disposing on the at least one substrate a first layer comprising a first transmission line and a second transmission line, the second transmission line configured to electromagnetically couple to the first transmission line, the second transmission line including at least one bend, the second transmission line spaced apart from the first transmission line to form a gap in the first layer between the first transmission line and the second transmission line; and
disposing on the at least one substrate a second layer comprising a metal structure configured to provide a ground for the first transmission line, the metal structure including an aperture positioned to at least partially overlap the gap in the first layer.
